(19) United States
(12) Patent Application Publication
(10) Pub. No.: US 2015/0270356 A1
(43) Pub. Date: Sep. 24, 2015

(54) VERTICAL NITRIDE SEMICONDUCTOR DEVICE

(71) Applicant: Massachusetts Institute of Technology, Cambridge, MA (US)

(72) Inventors: Tomas Apostol Palacios, Belmont, MA (US); Yuhao Zhang, Cambridge, MA (US)

(73) Assignee: Massachusetts Institute of Technology, Cambridge, MA (US)

(21) Appl. No.: 14/662,837

(22) Filed: Mar. 19, 2015

Related U.S. Application Data
(60) Provisional application No. 61/968,044, filed on Mar. 20, 2014.
(60) Provisional application No. 61/988,957, filed on May 6, 2014.

(51) Int. Cl. H01L 29/20; H01L 21/02; H01L 21/283; H01L 29/417

(52) U.S. Cl. CPC H01L 29/2003; H01L 29/417; H01L 21/0254; H01L 21/02458; H01L 21/283

(57) ABSTRACT

A vertical semiconductor device and a method of forming the same. A vertical semiconductor device has a substrate that includes a first material, a first electrode below the substrate, and at least one semiconductor region. The at least one semiconductor region includes a second material different from the first material. The second material is a III-nitride semiconductor material. The at least one semiconductor region is formed over the substrate. The vertical semiconductor device also has a second electrode over the at least one semiconductor region.

### CROSS-REFERENCE TO RELATED APPLICATIONS

This application claims priority to U.S. provisional application Ser. No. 61/968,044, titled “VERTICAL NITRIDE SEMICONDUCTOR DEVICE,” filed Mar. 20, 2014, and U.S. provisional application Ser. No. 61/988,957, titled “VERTICAL NITRIDE SEMICONDUCTOR DEVICE WITH CONDUCTIVE BUFFER LAYERS,” filed May 6, 2014, each of which is hereby incorporated by reference in its entirety.

### BACKGROUND

1. Field of Invention

The techniques described herein relate to vertical semiconductor devices, and in particular to vertical semiconductor devices including a III-nitride semiconductor material.

2. Discussion of the Related Art

Improved power transistors are desired for advanced transportation systems, more robust energy delivery networks and new approaches to high-efficiency electricity generation and conversion. Applications of power transistors include power supplies, automotive electronics, automated factory equipment, motor controls, traction motor drives, high voltage direct current (HVDC) electronics, lamp ballasts, telecommunications circuits and display drives, for example. Such systems rely on efficient converters to step-up or step-down electric voltages, and use power transistors capable of blocking large voltages and/or carrying large currents. In hybrid vehicles, for example, power transistors with blocking voltages of more than 500 V are used to convert DC power from the batteries to AC power to operate the electric motor.

Conventional power devices (e.g., transistors or diodes) used in such applications are made of silicon. However, the limited critical electric field of silicon and its relatively high resistance causes available commercial devices, circuits and systems to be very large and heavy, and operate at low frequencies. Therefore, such commercial devices are unsuitable for future generations of hybrid vehicles and other applications.

Nitride semiconductor devices have been proposed as offering the potential for producing high-efficiency power electronics demanding high blocking voltages and low on-resistances.

### SUMMARY

Some embodiments relate to a vertical semiconductor device. A vertical semiconductor device has a substrate that includes a first material, a first electrode below the substrate, and at least one semiconductor region. The at least one semiconductor region includes a second material different from the first material. The second material is a III-nitride semiconductor material. The at least one semiconductor region is formed over the substrate. The vertical semiconductor device also has a second electrode over the at least one semiconductor region.

Some embodiments relate to a method of forming a vertical semiconductor device. The method includes forming, over a substrate comprising a first material, at least one semiconductor region including a second material different from the first material. The second material is a III-nitride semiconductor material. The method also includes forming a first electrode on a first side of the substrate and a second electrode over the at least one semiconductor region on a second side of the substrate.

The foregoing summary is provided by way of illustration and is not intended to be limiting.

### BRIEF DESCRIPTION OF DRAWINGS

In the drawings, each identical or nearly identical component that is illustrated in various figures is represented by a like reference character. For purposes of clarity, not every component may be labeled in every drawing. The drawings are not necessarily drawn to scale, with emphasis instead being placed on illustrating various aspects of the techniques and devices described herein.

FIG. 1A shows a GaN vertical power device on a GaN substrate, having a fully-vertical geometry.

FIG. 1B shows a GaN power device on a non-GaN substrate, having a pseudo-vertical geometry.

FIG. 2A illustrates current flow in the vertical power device of FIG. 1A.

FIG. 2B illustrates current flow in the pseudo-vertical power device of FIG. 1B.

FIG. 3 shows a cross-sectional diagram illustrating an embodiment of a III-nitride vertical diode.

FIG. 4 shows a cross-sectional diagram illustrating an embodiment of a III-nitride vertical transistor: a metal insulator semiconductor field-effect transistor (MISFET).

FIG. 5 shows a cross-sectional diagram illustrating an embodiment of a III-nitride vertical transistor: a vertical insulated gate high electron mobility field-effect (HFET).

FIG. 6 shows a flowchart illustrating a method of fabricating a III-nitride based vertical device on a substrate of a different material, according to some embodiments.

FIG. 7 shows a cross-sectional diagram illustrating an embodiment of a III-nitride vertical diode having a conductive buffer region.

FIG. 8 shows a cross-sectional diagram illustrating an embodiment of a III-nitride vertical transistor having a conductive buffer region 22: a metal insulator semiconductor field-effect transistor (MISFET).

FIG. 9 shows a cross-sectional diagram illustrating an embodiment of a III-nitride vertical transistor having a conductive buffer region 22: a vertical insulated gate high electron mobility field-effect (HFET).

FIG. 10 shows a flowchart illustrating a method of fabricating a III-nitride vertical device having a conductive buffer region, according to some embodiments.

FIG. 11 shows a cross-sectional diagram illustrating an embodiment of a III-nitride vertical diode having a conductive substrate and a conductive buffer region.

FIG. 12 shows a cross-sectional diagram illustrating an embodiment of a III-nitride vertical transistor having a conductive substrate and a conductive buffer region: a metal insulator semiconductor field-effect transistor (MISFET).

FIG. 13 shows a cross-sectional diagram illustrating an embodiment of a III-nitride vertical transistor having a conductive substrate and a conductive buffer region: a vertical insulated gate high electron mobility field-effect (HFET).

FIG. 14 shows a flowchart illustrating a method of fabricating a III-nitride vertical device having a conductive substrate and a conductive buffer region, according to some embodiments.

### DETAILED DESCRIPTION

Both vertical and lateral devices have been considered for GaN power devices. Lateral structures, such as lateral AlGaN/GaN high-electron-mobility transistors, though they have been studied extensively, still face reliability and integration challenges. GaN vertical devices have attracted increased attention recently, due to their potential for sustaining high breakdown voltage (BV) without enlarging chip size, suitability to have the peak electric field away from the surface, and superior thermal performance. Recent demonstrations of high-performance vertical GaN diodes and transistors on GaN substrates have made vertical structures very promising for GaN power devices.

Despite the excellent performance demonstrated by GaN vertical devices, the high cost and small diameter of GaN substrates has been a significant obstacle for the development of GaN vertical power devices. Lower-cost non-GaN substrates for GaN vertical devices could significantly reduce the cost of the final device and facilitate their market insertion. Although several non-GaN substrates, such as sapphire and Si, have been used to reduce the cost of lateral GaN devices, there have been only few GaN vertical power devices on non-GaN substrates reported, with device performance very inferior to that of GaN vertical power devices on GaN substrates.

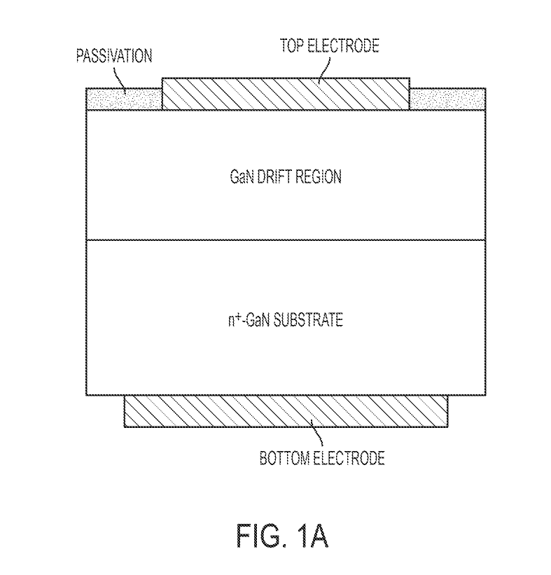

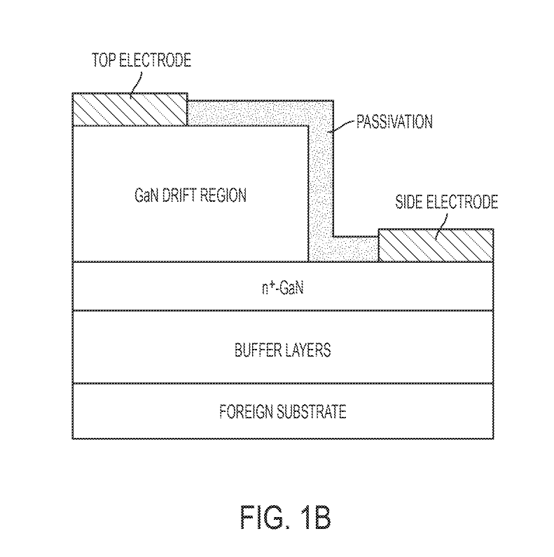

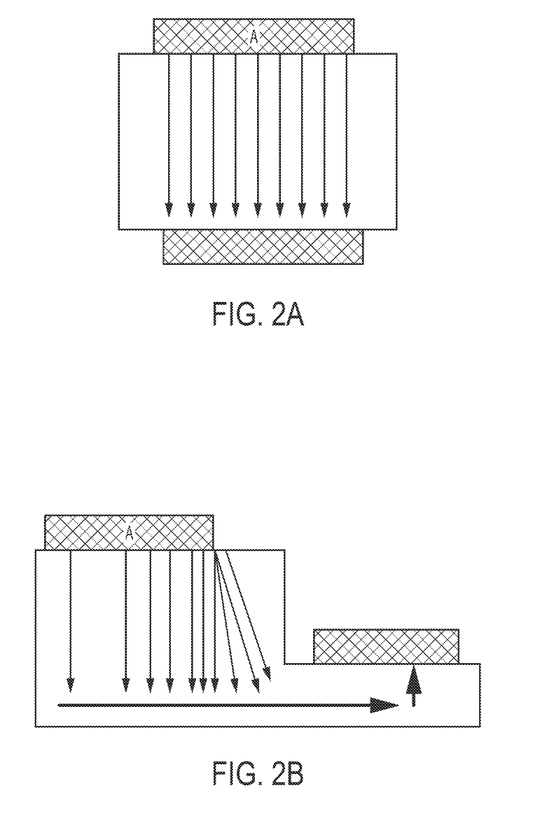

One main reason for the inferior performance of prior GaN vertical power devices on non-GaN substrates is related to their geometry. GaN vertical power devices on GaN substrates adopt a fully-vertical geometry, as shown in FIG. 1A and FIG. 2A. However, GaN vertical power devices on non-GaN substrates adopt a pseudo-vertical structure, as shown in FIG. 1B and FIG. 2B. This is due to the buffer layers between the GaN epitaxial layers and lattice-mismatched, non-GaN substrates, including the nucleation, adhesion and transition layers, being highly-resistive and of low quality. Compared to a fully-vertical structure, a pseudo-vertical structure leads to inferior device performance due to two main reasons. First, the fabrication of pseudo-vertical structures typically involves a deep etch of GaN in order to form side electrodes. The high ion energy used for GaN dry etching can induce damage at the vertical etching sidewalls. This can lead to a large leakage current along the etching sidewall or at the interface between the GaN and passivation layers, which increases the device reverse leakage current. Second, the pseudo-vertical structure may lead to a larger on-resistance compared to fully-vertical structures. As shown in the schematic current distribution illustrated in FIG. 2A, the current in a fully vertical structure has essentially only a vertical component. However, as shown in FIG. 2B, the current in a pseudo-vertical device has a lateral component and accumulates below the anode contact edge due to the higher electric field at that location. This non-uniform current distribution leads to an increase in device on-resistance.

As should be appreciated from the above, producing vertical III-N semiconductor devices on substrates of different materials can reduce the cost and increase the performance of III-N semiconductor devices, such as GaN devices. Described herein are device structures and fabrication methods that can achieve fully-vertical III-N semiconductor devices (e.g., GaN devices) on a substrate formed of a material different from that of the overlying III-N semiconductor layer(s). For example, if the III-N semiconductor layer(s) of a semiconductor device are formed of GaN, the substrate may be a non-GaN substrate formed of a different material than GaN such as silicon, sapphire, aluminum nitride, etc. The methods and techniques described herein can be applied to any of a variety of compound semiconductor systems to enable the fabrication of a vertical device on a substrate of a different material. Embodiments of vertical devices, such as vertical diodes and vertical transistors, and fabrication methods for forming such devices, are described herein.

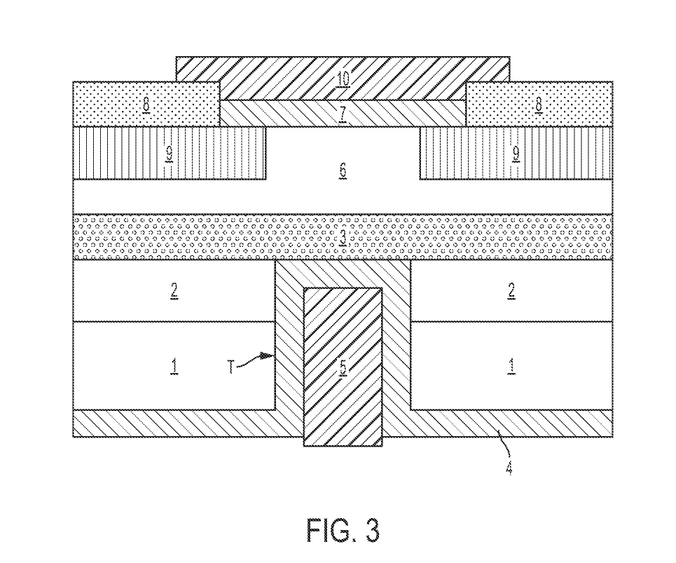

FIG. 3 shows a cross-sectional diagram illustrating a III-nitride vertical diode, according to some embodiments. The vertical diode is formed on a substrate 1 of different material than a III-nitride semiconductor material of a layer formed over the substrate 1, as discussed further below. In some embodiments, the substrate 1 may be a low-cost substrate. For example, in some embodiments the substrate 1 may be a wafer, such as a semiconductor wafer, or a portion of a semiconductor wafer (e.g., a semiconductor chip). Non-limiting examples of suitable materials for substrate 1 include a group IV semiconductor material such as silicon (Si), sapphire, diamond, graphene, and a compound semiconductor material such as silicon carbide (SiC), zinc oxide (ZnO), and aluminum nitride (AlN). The substrate 1 can be conductive, semiconductive, or non-conductive. If substrate 1 includes a semiconductor material, the semiconductor material may have any suitable conductivity type, including but not limiting to n-type, p-type or undoped-type.

A buffer region 2 is disposed over the substrate 1. Buffer region 2 may buffer a crystal lattice mismatch between the substrate 1 and the III-N semiconductor material to be formed over the substrate 1. Buffer region 2 may include a single layer or a plurality of layers. Examples of the types of layers that may be included in buffer region 2 include adhesion, nucleation, and/or lattice constant transition layers and/or other layers for promoting the growth of the III-nitride epitaxial layers on a lattice-mismatched substrate. In some embodiments, buffer region 2 has one or more lattice constant transition layers or strain relief and management layers. The lattice constant transition layers may gradually change the effective in-plane lattice constant at respective positions along the thickness of the buffer region 2, such that the effective in-plane lattice constant varies from being matched to the lattice constant of the underlying substrate 1 at the bottom surface of buffer region 2 to being matched to the lattice constant of the overlying III-nitride semiconductor material at the top surface of buffer region 2. The strain relief and management layers may relieve the excess strain in the structure to prevent cracks and defects. To effect a change in in-plane lattice constant or strain relief, the buffer region 2 may have a superlattice structure and/or may be compositionally graded. Any suitable materials may be included in buffer region 2, including a III-V semiconductor material such as a III-nitride semiconductor material, non-limiting examples of which include a binary III-nitride semiconductor material such as AN or GaN, a ternary III-nitride semiconductor material such as InGaN or AlGaN, and a quaternary III-nitride semiconductor material such as AlInGaN.

One or more layers of III-nitride semiconductor material may be formed over the buffer region 2. In the embodiment of FIG. 3, a layer of III-nitride semiconductor material 3 is disposed over the buffer region 2. In some embodiments, the III-nitride semiconductor material of layer 3 may include a GaN semiconductor material.

The terms “III-nitride semiconductor material,” “III-N semiconductor material,” and “nitride semiconductor material” refer to a III-V semiconductor material having nitrogen bonded to a group III element. Such terms do not preclude the possibility that other elements may be present, such as dopants, for example. In some embodiments, a III-nitride semiconductor material may have a composition of B_{w}AlₓIn_{y}Ga_{z}N, for example, in which w, x, y and z each have any suitable value between zero and one (inclusive of zero and one), and w+x+y+z=1. A III-nitride semiconductor material may be binary, ternary, quaternary, or have any other suitable number of elements. The term “GaN semiconductor material” refers to a III-nitride semiconductor material having nitrogen bonded to gallium, and does not preclude the possibility that other elements may be present.

The layer of III-nitride semiconductor material 3 may be conductive. In some embodiments, the layer of III-nitride semiconductor material 3 can be highly doped to facilitate the formation of an ohmic contact on the bottom of layer 3 to a bottom electrode. For example, the layer of III-nitride semiconductor material 3 may be n⁺ (or p⁺) doped, with dopant concentrations ranging from 1×10¹⁵ cm⁻³ to 1×10²⁰ cm⁻³, although the techniques described herein are not limited to a particular doping concentration.

Alternatively or additionally, the III-nitride semiconductor material 3 may be doped by polarization-induced doping.

As shown in FIG. 3, a portion of the substrate 1 and the buffer region 2 may be removed, forming a trench T at the bottom of the structure and exposing the bottom of the layer of III-nitride semiconductor material 3. In some embodiments, the sidewalls of the trench T may be vertical. However, in some embodiments, the sidewalls may be non-vertical, e.g., leaning. The bottom electrode 4 may cover the entire back side of the wafer, as shown in FIG. 3, or just a localized region.

A bottom electrode 4 may be formed on the bottom of the substrate 1 in the trench T to electrically contact the layer of III-nitride semiconductor material 3. As shown in FIG. 3, the bottom electrode 4 may be formed such that it physically contacts the layer of III-nitride semiconductor material 3 in the trench T. Since the bottom electrode 4 is electrically connected to the layer of III-nitride semiconductor material 3 in the trench T, the substrate 1 and the buffer region 2 can be non-conductive, as current can flow directly between the bottom electrode 4 and the layer of III-nitride semiconductor material 3, bypassing the buffer region 2 and the substrate 1. However, substrate 1 and buffer region 2 may have any conductivity, and may be conductive or semi-conductive, in some embodiments. In some embodiments in which substrate 1 and buffer region 2 are conductive or semi-conductive, an additional current path may be present between the layer of III-nitride semiconductor material 3 and the bottom electrode 4 through the substrate 1 and buffer region 2, in addition to the direct current path between the layer of III-nitride semiconductor material 3 and the bottom electrode 4 in the trench T. In some embodiments of a vertical diode, the bottom electrode 4 may be the cathode electrode of the vertical diode. In some embodiments of a vertical transistor, as discussed further below, the bottom electrode 4 may be the drain electrode. However, the techniques described herein are not limited in this respect, as the electrode 4 may form any suitable terminal of a device, including an anode electrode of a vertical diode, a source electrode of a vertical transistor, etc. Electrode 4 may be formed of any suitable conductor, such as a metal or doped semiconductor, by way of example.

In some embodiments, at least a portion of the trench T may be filled with a fill region 5, as shown in FIG. 3. The fill region 5 may be deposited on the back side of the wafer, such that it is disposed in the trench under the bottom electrode 4. In some embodiments, fill region 5 may include a thermally conductive material to facilitate dissipation of heat from the structure. Fill region 5 may have any suitable electrical conductivity, and may be electrically conductive, semi-conductive or insulating. Non-limiting examples of thermally conductive materials that may be included in fill region 5 include a metal, diamond, a dielectric such as AN, for example, and a polymer composite.

As shown in FIG. 3, a region 6 may be disposed over the layer of III-nitride semiconductor material 3. Region 6 may have one or more layers that serve as a drift region for the device. Region 6 may be formed of a III-nitride semiconductor material. In the device's conductive state (on-state), region 6 may be a region through which current can flow in a vertical direction between the top electrode 7 and the bottom electrode 4. In the device's non-conductive state (off-state), region 6 can support the electric field created by the voltage gradient between the top electrode 7 and the bottom electrode 4. In some embodiments, a plurality of junctions may be formed within region 6, such as heterojunctions, p-n junctions, etc. In some embodiments, region 6 may have a thickness in the vertical dimension of FIG. 3 (as measured between the top electrode 7 and the layer of III-nitride semiconductor material 3) of between 1 μm and 100 μm. The thickness of region 6 can differ substantially depending on the desired functionality (e.g., the desired breakdown voltage). Different thicknesses can be selected to cover the spectrum from low breakdown voltage devices to very high breakdown voltage devices.

Some embodiments of diodes or transistors may have breakdown voltages of at least 100 V, at least 200 V, at least 600 V, at least 1,200 V, at least 5,000 V, at least 10 kV, or at least 20 kV, by way of example. In some embodiments, the III-nitride semiconductor material of region 6 may be doped. If the III-nitride semiconductor material is doped, it may be intentionally doped n-type or p-type, polarization doped, and/or unintentionally doped. The doping concentration may be relatively low (e.g., n⁻ type or p⁻ type). In some embodiments, region 6 may include both n-type and p-type doped III-nitride layers to form p-n junctions and/or to provide channel layer(s) for a field-effect transistor.

In the embodiment of a III-nitride vertical diode shown in FIG. 3, an upper electrode 7 may be disposed on the region 6. Upper electrode 7 may be an anode electrode (or a cathode electrode) of the III-nitride vertical diode. Upper electrode 7 may be formed of any suitable conductor, such as a metal or doped semiconductor, by way of example. Upper electrode 7 may be a Schottky electrode or an ohmic electrode. In some embodiments, a layer of dielectric material 8 may be disposed on the top surface of the structure as a passivation layer. Non-limiting examples of the materials that may be used for dielectric layer 8 include SiO₂, SiₓN_{y}, SiₓO_{y}N_{z}H_{w}, Al₂O₃, and HfO₂. In some embodiments, an edge termination region 9 may be formed to spread a high electric field that may be present at the edge of upper electrode 7. In some embodiments, edge termination region 9 may be a region of III-nitride semiconductor material. In some embodiments, edge termination region 9 may be formed of the same III-nitride semiconductor material as region 6. In some embodiments, the edge termination region 9 may be highly resistive. To make edge termination region 9 highly resistive, it may be highly doped by any of a variety of dopants, including but not limiting to magnesium, carbon, beryllium, zinc, or the like. In some embodiments the edge termination region 9 may be formed by ion implantation, with the ions including but not limiting to magnesium, argon, fluorine, or the like. In some embodiments, the edge termination region 9 may have a graded doping concentration. In some embodiments, a conductive layer 10 may be disposed on top of upper electrode 7 and/or dielectric layer 8, forming a field plate structure. The conductive layer 10 may be formed of any suitable conductor, such as a metal or doped semiconductor. The field plate structure can assist in spreading a high electric field that may be present at the edge of upper electrode 7, and may lower the reverse leakage current and/or enhance the breakdown voltage of the device.

Some embodiments relate to III-nitride vertical transistors. In some embodiments, the III-nitride vertical transistors may have one or more of the same regions as those included in the vertical diode illustrated in FIG. 3, such as regions 1-6, for example.

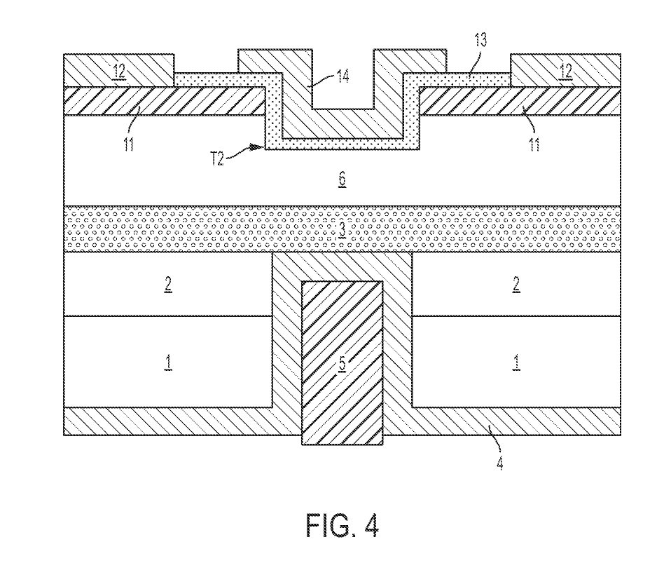

FIG. 4 shows a cross-sectional diagram illustrating an embodiment of a III-nitride vertical transistor: a III-nitride based vertical metal insulator semiconductor field-effect transistor (MISFET). Regions 1-6 of the vertical transistor may be the same as or similar to regions 1-6 discussed above with respect to FIG. 3. In some embodiments, region 6 of the MISFET may include both an n⁻-type (or p⁻-type) III-nitride layer as a drift layer as well as a p⁺-type (or n⁺-type) III-nitride layer as a channel layer. A III-nitride layer 11 may be disposed on region 6. III-nitride layer 11 may be formed of the same semiconductor material as region 6 or a different semiconductor material. In some embodiments, III-nitride layer 11 may be highly-doped to facilitate the formation of an ohmic contact to a source electrode 12. In some embodiments, III-nitride layer 11 may dope the interface between regions 11 and 6 through polarization doping. An electrode 12 formed of any suitable conductor may be formed on layer 11 to serve as a source electrode for the vertical transistor. As shown in FIG. 4, on the top surface of the transistor a trench T2 may be formed through the III-nitride layer 11 into region 6. A dielectric layer 13 may be disposed within the trench to serve as a gate dielectric for the vertical transistor. Non-limiting examples of materials of dielectric layer 13 include SiO₂, SiₓN_{y}, AlN, Al₂O₃, and HfO₂. A gate electrode 14 for the vertical transistor may be disposed over dielectric layer 13. Gate electrode 14 may be formed of any suitable conductor.

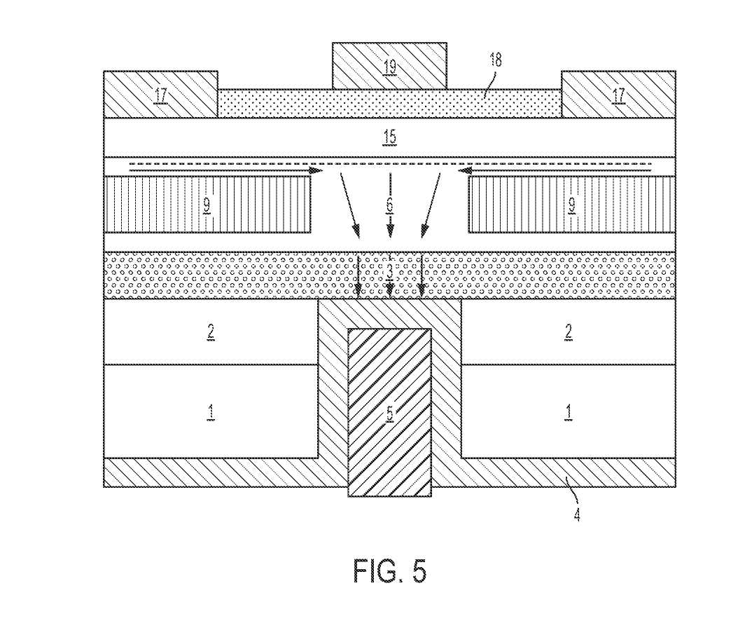

Some embodiments of III-nitride vertical transistors include III-nitride vertical insulated gate HFETs or III-nitride vertical heterojunction field-effect transistors (HFETs). FIG. 5 shows a simplified cross-sectional diagram illustrating an embodiment of a III-nitride vertical insulated gate HFET. Regions 1-6 of the HFET may be the same as those in the vertical diode or MISFET described above. A III-nitride layer 15 may be disposed on region 6. The III-nitride semiconductor material of layer 15 may be formed of a different material from that of the III-nitride semiconductor material of region 6, and may have a higher bandgap than that of region 6. In some embodiments, layer 15 may be undoped or unintentionally doped. In some embodiments, the materials of layer 15 and region 6 can be InAlGaN and GaN, respectively, AlGaN and GaN, respectively or InGaN and GaN, respectively. The III-nitride semiconductor material of layer 15 may be lattice-mismatched with respect to the III-nitride semiconductor material of region 6. In such embodiments, a two dimensional electron gas (2DEG) layer/channel is formed at the heterointerface between layer 15 and region 6. Two highly-resistive blocking regions 9 may be formed to restrict the flow of current to within the aperture between the blocking regions 9. Source electrodes 17 may be disposed over layer 15 and electrically connected to the 2DEG. A dielectric layer 18 and a gate electrode 19 form an insulated gate structure to modulate the 2DEG for the vertical HFET.

A variety of different types of transistors and diodes can be formed using the structures and techniques as described herein. Other types of transistors that may be formed according to such techniques besides field effect transistors and HEMTs include, and are not limited to III-nitride vertical superjuction devices, III-nitride vertical insulated-gate bipolar transistors, and III-nitride vertical junction field-effect transistors. Such transistors and diodes may include regions 1-6 as described herein, which can provide a modular supporting structure that can be used to construct a variety of types of vertical devices.

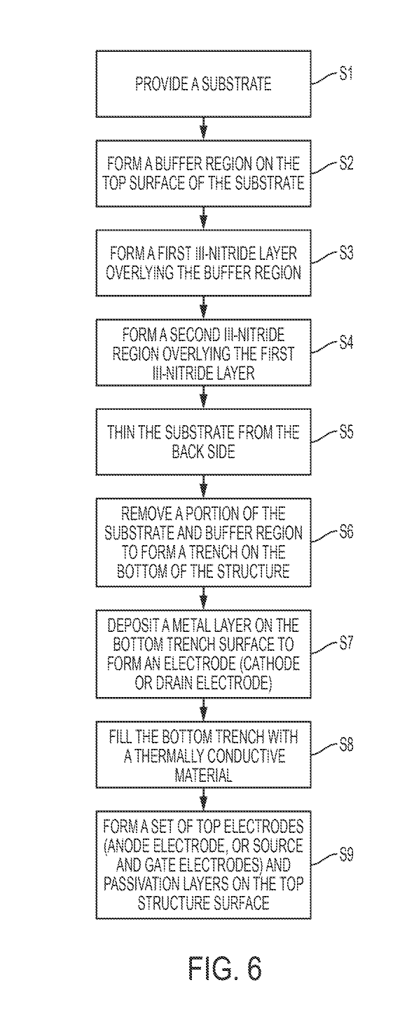

FIG. 6 shows a flowchart illustrating a method of fabricating a III-nitride based vertical device on a substrate of a different material, such as the devices of FIGS. 3-5, according to some embodiments. In step S1, a substrate 1 is provided. Steps S2-S4 involve the growth of a buffer region 2, III-nitride layer 3 and region 6. Any of a variety of techniques can be used for the growth of such layers, including but not limiting to Metal-Organic Chemical Vapor Deposition (MOCVD), Molecular Beam Epitaxy (MBE), and/or Metal-Organic Vapor Phase Epitaxy (MOVPE). In step S2, a buffer region 2 may be formed on the substrate 1. As discussed above, the buffer region 2 may include one or more layers such as adhesion, nucleation, transition and/or other layer(s). In step S3, a III-nitride layer 3 may be formed over the buffer region. In step S4, region 6 may be formed over the III-nitride layer 3.

In step S5, the thickness of the substrate 1 may be reduced, in some embodiments. Thinning the substrate may make it easier to fabricate the trench T, and may facilitate dissipation of heat from the vertical device. Any suitable techniques may be used for thinning substrate 1, such as physical and/or chemical methods, including but not limited to chemical-mechanical polishing/planarization, dry etching, wet etching, etc.

In step S6, the trench T may be formed in the substrate 1 and buffer region 2. To form the trench T, at least a portion of the substrate 1 and at least a portion of the buffer region 2 may be removed. Any suitable material removal technique may be used for forming the trench, such as dry etching, by way of example and not limitation. If dry etching is used, any suitable ions may be used, including but not limited to argon, fluorine, oxygen, hydrogen, nitrogen, chlorine and/or sulfur ions. In some embodiments having a buffer region 2 including a III-nitride semiconductor material, the buffer region can be etched using fluorine-based or chlorine-based plasma. In some embodiments in which the substrate 1 is a silicon substrate, fluorine-based plasma may be used to etch the silicon substrate 1. If fluorine-based plasma is used for the dry etching, any suitable gases can be used, including but not limited to CF₄, SF₆ and/or CHF₃. If chlorine-based plasma is used for the dry etching, any suitable gases can be used, including but not limited to Cl₂ and/or BCl₃. In some embodiments, the dry etching may be steadily controlled, produce a smooth etching sidewall and induce minimum or no damage on the III-nitride layer 3.

In step S7, the bottom electrode 4 may be formed. Any suitable technique may be used for forming the bottom electrode 4, such as electron beam (ebeam) deposition or sputtering, by way of example and not limitation. In some embodiments, post annealing may be performed after forming the bottom electrode 4 to reduce its contact resistance.

In step S8, the trench T may be filled with a fill material 5 using any suitable deposition technique.

In step S9, the remaining layers may be formed such as passivation layer 8, a set of top electrodes on the top structure surface, such as an anode electrode for a vertical diode and source and gate electrodes for vertical transistors.

As will be appreciated by those of ordinary skill in the art, any of a variety of steps or fabrication methods may be used for formation of other layers of the vertical diode and transistors discussed above with respect to FIG. 3, FIG. 4 and FIG. 5.

### Conductive Buffer Region

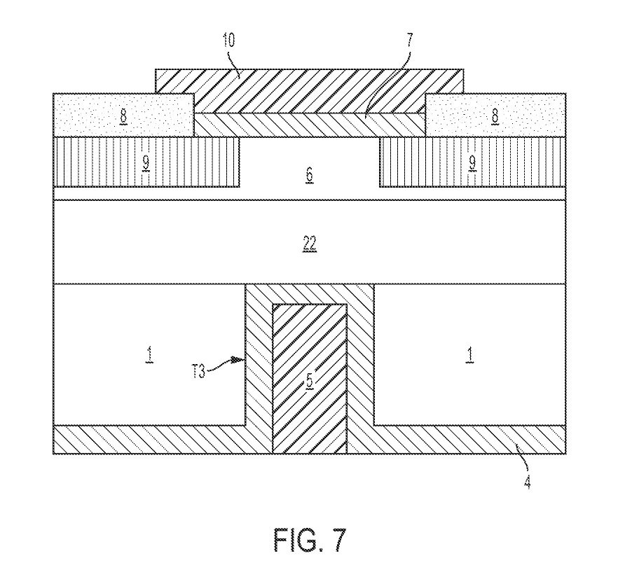

In some embodiments, a vertical III-nitride device may be formed with a conductive buffer region. FIG. 7 shows an embodiment of a vertical III-nitride diode having a trench T3 formed through the substrate 1 so that bottom electrode 4 can make contact to a conductive buffer region 22. Substrate 1 may have any suitable electrical conductivity, including insulating, conductive or semiconducting. The trench T3 may be formed by removing a region of the substrate 1 and optionally removing a portion of the buffer region 22. The sidewalls of the trench T3 may be vertical or non-vertical. A bottom electrode 4 is disposed in the trench T3. In some embodiments, the trench T3 may be filled with a fill region 5, which optionally may be a thermal conductor to facilitate heat dissipation, as discussed above. In some embodiments, the bottom part of the buffer region 22 may be heavily doped to facilitate a good ohmic contact with bottom electrode 4.

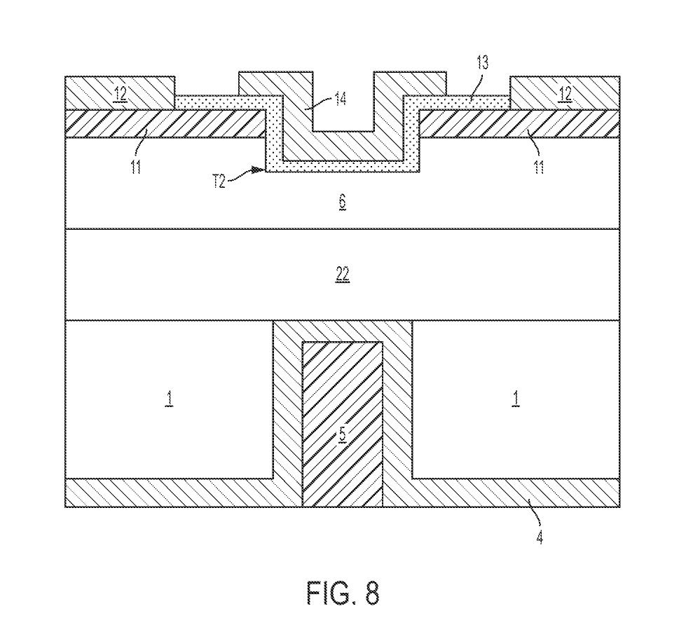

FIG. 8 shows a cross-sectional diagram illustrating an embodiment of a III-nitride vertical transistor having a conductive buffer region 22: a metal insulator semiconductor field-effect transistor (MISFET). The MISFET has underlying regions 1, 22, 4 and 5 as discussed above with respect to FIG. 7, as well as upper regions of the MISFET as discussed above with respect to FIG. 4

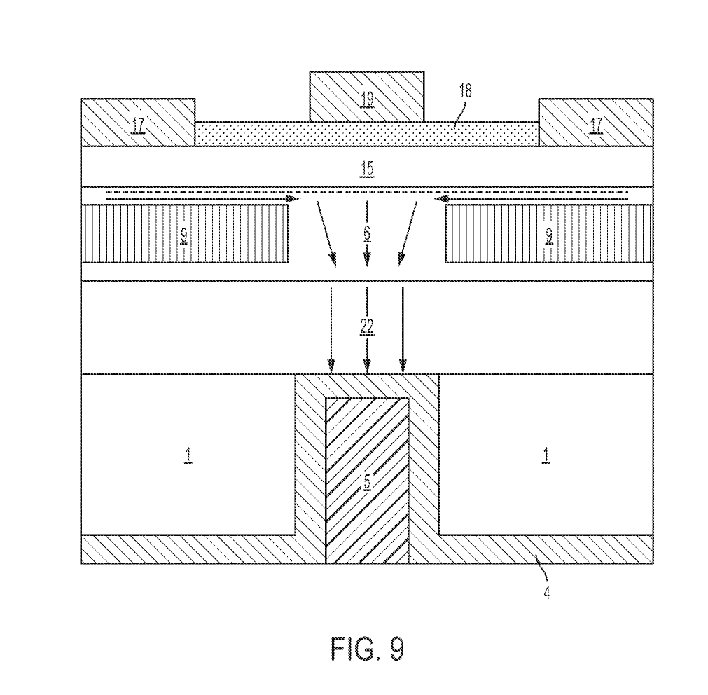

FIG. 9 shows a cross-sectional diagram illustrating an embodiment of a III-nitride vertical transistor having a conductive buffer region 22: a vertical insulated gate high electron mobility field-effect (HFET). The HFET has underlying regions 1, 22, 4 and 5 as discussed above with respect to FIG. 7, as well as upper regions of the HFET as discussed above with respect to FIG. 5.

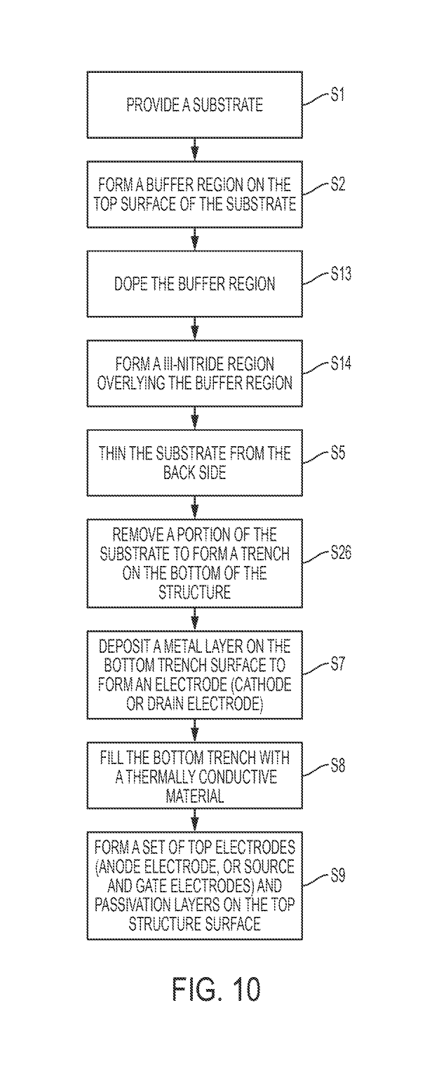

FIG. 10 shows a diagram illustrating a method of fabricating a III-nitride vertical device, such as the devices of FIGS. 7-9, according to some embodiments. In step S1, a substrate 1 is provided. Buffer region 22 is formed in step S2. In some embodiments, buffer region 22 may be the same or similar to buffer region 2, discussed above. The buffer region 22 may include one or more layers such as adhesion, nucleation, transition and/or other layer(s). In step S13, the buffer region 22 is doped to make buffer region 22 conductive. Step S13 may be performed concurrently with step S2 by implementing the doping in situ during the growth of buffer region 22. In some embodiments, step S13 may be performed after the growth of buffer region 22 by techniques including but not limited to plasma treatment and ion implantation. Any suitable dopants may be used. If the buffer region 22 includes a III-V semiconductor material it may be doped with silicon for n-type doping or magnesium for p-type doping, by way of example and not limitation. Various optional techniques may be used for dopant activation, including but not limiting to thermal annealing and/or electron beam irradiation. In step S14, region 6 may be formed, which may include a plurality of layers as discussed above. In optional step S5, the thickness of the substrate 1 may be reduced, in some embodiments. The trench T3 is formed in step S26 by any suitable material removal technique, such as those discussed above with respect to step S6. Steps S7-S9 may be the same as or similar to those discussed above with respect to FIG. 6.

A variety of different types of transistors and diodes can be formed using the structures and techniques as described with respect to FIGS. 7-10. Examples of transistors that may be formed according to such techniques include, and are not limited to field effect transistors, HEMTs, superjuction devices, vertical insulated-gate bipolar transistors, and vertical junction field-effect transistors. Such transistors and diodes may include regions 1, 22, 4 and 5 as described herein, which can provide a modular supporting structure that can be used to construct a variety of types of vertical devices using a conductive buffer region.

### Conductive Substrate and Conductive Buffer Region

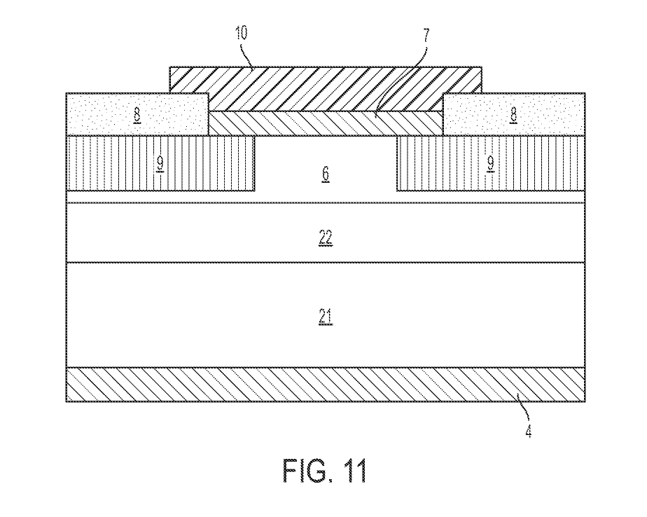

In some embodiments, a vertical III-nitride device may be formed with a conductive substrate and a conductive buffer region. FIG. 11 shows a cross-sectional diagram illustrating an embodiment of a III-nitride based vertical diode including a conductive substrate 21 and a conductive buffer region 22. Buffer region 22 is disposed over a conductive substrate 21. A bottom electrode 4 is disposed on the surface of substrate 21. The remaining layers of the vertical diode may be provided as discussed above with respect to FIG. 3. Accordingly, using a conductive substrate 21 and a conductive buffer region 22, a vertical III-nitride diode may be formed on a substrate 21 of different material from an overlying III-nitride semiconductor material, without requiring forming a trench in the substrate to make contact to a conductive region overlying the substrate.

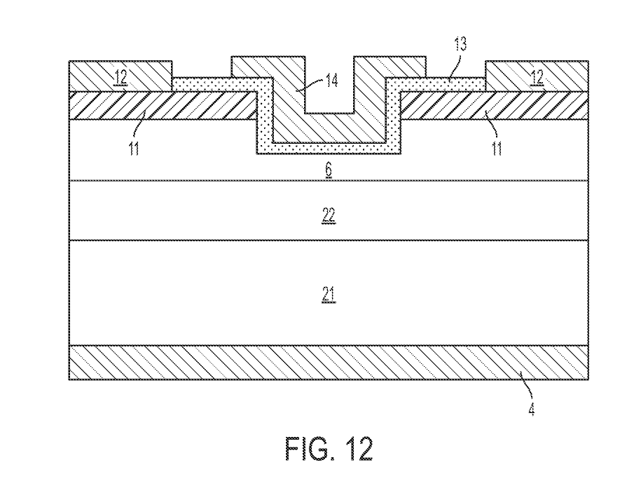

FIG. 12 shows a cross-sectional diagram illustrating an embodiment of a III-nitride vertical transistor having a conductive substrate 21 and a conductive buffer region 22: a metal insulator semiconductor field-effect transistor (MISFET). The MISFET has underlying regions 21, 22, and 4 as discussed above with respect to FIG. 11, as well as upper regions of the MISFET as discussed above with respect to FIG. 4.

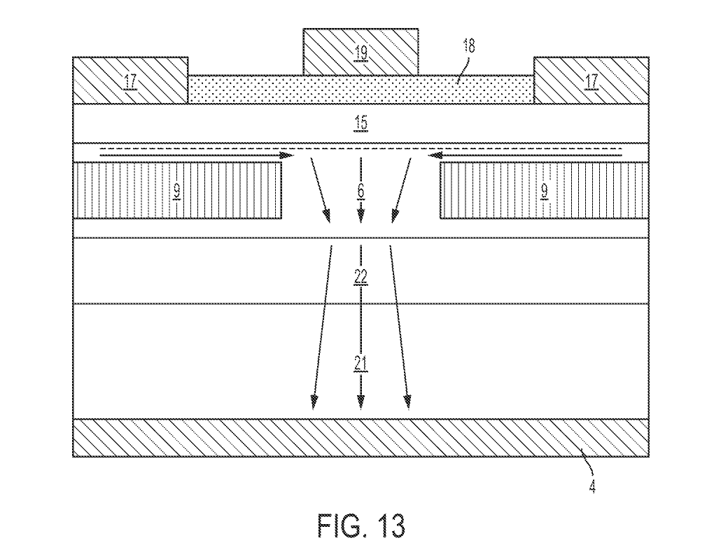

FIG. 13 shows a cross-sectional diagram illustrating an embodiment of a III-nitride vertical transistor having a conductive substrate 21 and a conductive buffer region 22: a vertical insulated gate high electron mobility field-effect (HFET). The HFET has underlying regions 21, 22, and 4 as discussed above with respect to FIG. 11, as well as upper regions of the HFET as discussed above with respect to FIG. 5.

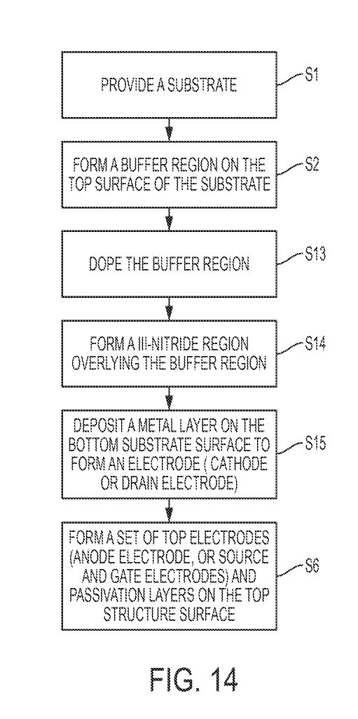

FIG. 14 shows a diagram illustrating a method of fabricating a III-nitride vertical device having a conductive substrate and a conductive buffer region, such as the devices of FIGS. 11-13, according to some embodiments. The first four steps, steps S1, S2, S13 and S14, may be the same as or similar to those discussed above with respect to FIG. 10. In step S15, the bottom electrode 4 may be formed using any suitable technique, such as those discussed above. In step S6, the remaining layers may be formed such as passivation layer 8, a set of top electrodes on the top surface, such as an anode electrode for a vertical diode and/or source and gate electrodes for a vertical transistor.

A variety of different types of transistors and diodes can be formed using the structures and techniques as described with respect to FIGS. 11-14. Other types of transistors that may be formed according to such techniques besides field effect transistors and HEMTs include, and are not limited to III-nitride vertical superjuction devices, III-nitride vertical insulated-gate bipolar transistors, and III-nitride vertical junction field-effect transistors. Such transistors and diodes may include regions 21, 22 and 4 as described herein, which can provide a modular supporting structure that can be used to construct a variety of types of vertical devices having a conductive substrate and a conductive buffer region.

### Additional Aspects

Various aspects of the apparatus and techniques described herein may be used alone, in combination, or in a variety of arrangements not specifically discussed in the embodiments described in the foregoing description and is therefore not limited in its application to the details and arrangement of components set forth in the foregoing description or illustrated in the drawings. For example, aspects described in one embodiment may be combined in any manner with aspects described in other embodiments.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items. For example, an apparatus, structure, device, layer, or region recited as “including,” “comprising,” or “having,” “containing,” “involving,” a particular material is meant to encompass at least the material listed and any other elements or materials that may be present. The partially open-ended phrase “consisting essentially of” is meant to encompass essentially the material listed and does not preclude the presence of relatively small quantities of other materials, including the presence of dopants.

The terms “layer” and “region” are used interchangeably herein. Use of one term as opposed to the other is not meant to connote any difference in the shape, structure or method of fabricating the referenced “layer” or “region.”

What is claimed is:

1. A vertical semiconductor device, comprising:
a substrate comprising a first material;
a first electrode below the substrate;
at least one semiconductor region comprising a second material different from the first material, the second material being a III-nitride semiconductor material, the at least one semiconductor region being formed over the substrate; and
a second electrode over the at least one semiconductor region.

2. The vertical semiconductor device of claim 1, wherein the second material is lattice-mismatched with respect to the first material.

3. The vertical semiconductor device of claim 2, wherein the vertical semiconductor device comprises a buffer region between the substrate and the at least one semiconductor region that buffers a lattice mismatch between the first material and the second material.

4. The vertical semiconductor device of claim 3, wherein the buffer region is compositionally graded or has a superlattice structure.

5. The vertical semiconductor device of claim 3, wherein the buffer region comprises a III-nitride semiconductor material.

6. The vertical semiconductor device of claim 1, wherein the at least one semiconductor region comprises a plurality of semiconductor regions.

7. The vertical semiconductor device of claim 6, wherein the plurality of semiconductor regions comprises a first semiconductor region comprising a III-nitride semiconductor material and a second semiconductor region comprising a III-nitride semiconductor material.

8. The vertical semiconductor device of claim 7, wherein the first semiconductor region has a higher conductivity than that of the second semiconductor region.

9. The vertical semiconductor device of claim 8, wherein the first semiconductor region contacts the first electrode.

10. The vertical semiconductor device of claim 8, wherein the second semiconductor region comprises a drift region.

11. The vertical semiconductor device of claim 1, wherein the III-nitride semiconductor material comprises a gallium nitride semiconductor material.

12. The vertical semiconductor device of claim 1, wherein the substrate comprises a compound semiconductor material, a group IV semiconductor material, an oxide material, graphene or sapphire.

13. The vertical semiconductor device of claim 12, wherein the substrate comprises a semiconductor material that is lattice mismatched with respect to the III-nitride semiconductor material.

14. The vertical semiconductor device of claim 13, wherein the semiconductor material comprises an aluminum nitride semiconductor material.

15. The vertical semiconductor device of claim 1, further comprising a trench formed in the substrate.

16. The vertical semiconductor device of claim 15, wherein the first electrode is disposed in the trench.

17. The vertical semiconductor device of claim 16, further comprising a thermally conductive fill material in the trench.

18. The vertical semiconductor device of claim 16, wherein the vertical semiconductor device comprises a buffer region between the substrate and the at least one semiconductor region.

19. The vertical semiconductor device of claim 18, wherein the trench is further formed in the buffer region and the first electrode contacts the at least one semiconductor region in the trench.

20. The vertical semiconductor device of claim 19, wherein the buffer region is electrically insulating, the substrate is electrically insulating or both the buffer region and the substrate are electrically insulating.

21. The vertical semiconductor device of claim 18, wherein the buffer region is electrically conductive and the first electrode contacts the buffer region in the trench.

22. The vertical semiconductor device of claim 21, wherein a bottom of the buffer region is doped to form an ohmic contact with the first electrode

23. The vertical semiconductor device of claim 21, wherein the substrate is electrically insulating.

24. The vertical semiconductor device of claim 1, wherein the vertical semiconductor device comprises a buffer region between the substrate and the at least one semiconductor region, wherein the buffer region is electrically conductive and the substrate is electrically conductive.

25. The vertical semiconductor device of claim 1, wherein the vertical semiconductor device comprises a diode or a transistor.

26. A method of forming a vertical semiconductor device, the method comprising:
forming, over a substrate comprising a first material, at least one semiconductor region comprising a second material different from the first material, the second material being a III-nitride semiconductor material; and
forming a first electrode on a first side of the substrate and a second electrode over the at least one semiconductor region on a second side of the substrate.

27. The method of claim 26, further comprising forming a buffer region over the substrate and below the at least one semiconductor region, wherein the at least one semiconductor region is formed over the buffer layer.

28. The method of claim 27, further comprising thinning the substrate.

29. The method of claim 28, further comprising forming a trench in the substrate, wherein the first electrode is formed in the trench.

30. The method of claim 29, further comprising filling the trench with a thermally conductive material.

31. The method of claim 28, wherein the trench is further formed in the buffer region.

32. The method of claim 27, further comprising doping the buffer region.
